(19) United States
(12) Patent Application Publication
(10) Pub. No.: US 2026/0033287 A1
(43) Pub. Date: Jan. 29, 2026

(54) HYBRID COMPOSITE ELECTROSTATIC CHUCK

(71) Applicant: WATLOW ELECTRIC MANUFACTURING COMPANY, ST. LOUIS, MO (US)

(72) Inventors: Joaquin A. SANTILLAN, Gilbert, AZ (US); Sanhong ZHANG, Wildwood, MO (US)

(73) Assignee: WATLOW ELECTRIC MANUFACTURING COMPANY, ST. LOUIS, MO (US)

(21) Appl. No.: 19/348,896

(22) Filed: Oct. 3, 2025

Related U.S. Application Data
(63) Continuation of application No. PCT/US2024/022665, filed on Apr. 2, 2024.
(60) Provisional application No. 63/456,614, filed on Apr. 3, 2023.

(51) Int. Cl. H01L 21/683

(52) U.S. Cl. CPC H01L 21/6833

(57) ABSTRACT

An electrostatic chuck (ESC) for use in semiconductor processing includes a main body comprising an upper mounting surface, the upper mounting surface defining a surface profile and a guide plate coupled to the upper mounting surface of the main body. The guide plate includes a lower mounting surface. The lower mounting surface defines a surface profile that follows the surface profile of the upper mounting surface of the main body. The ESC further includes a heater embedded within the main body and a radio frequency (RF) electrode embedded within the guide plate. The main body is coupled to the guide plate via a connection consisting of a mechanical interlock.

### CROSS-REFERENCE TO RELATED APPLICATIONS

This application is a continuation of International Application No. PCT/US2024/022665, filed on Apr. 2, 2024, which claims priority to U.S. provisional application No. 63/456,614 filed on Apr. 3, 2023. The disclosures of the above applications are incorporated herein by their reference.

### FIELD

The present disclosure relates to semiconductor processing chambers, and more particularly to electrostatic chucks (ESCs) for use in such processing chambers.

### BACKGROUND

The statements in this section merely provide background information related to the present disclosure and may not constitute prior art.

Semiconductor wafers are produced by applying various processes such as deposition, etching, ion implanting and cleaning between processes. Each process is performed in a chamber that needs to maintain an environmentally controlled work atmosphere. These chambers are often equipped with chucks to hold the wafers.

The chucks can be mechanical, vacuum, or electrostatic. Mechanical chucks stabilize wafers on a supporting surface by using mechanical holders. Vacuum chucks operate by lowering the pressure between the wafer and the chuck below that of the chamber, and a radio frequency (RF) electrode holds the wafer against the upper surface of the chuck. Electrostatic chucks (ESCs), on the other hand, stabilize and hold wafers utilizing electrostatic forces generated by a voltage difference between the wafer and the RF electrode. Generally, ESCs apply a more uniform force than mechanical chucks or vacuum chucks.

As shown in FIG. 1, an electrostatic semiconductor processing system 5 includes a processing chamber 10, an ESC 12 sealed in the processing chamber 10, a voltage supply 14 to supply voltage to the ESC 12, and an RF generator 16 to supply RF power to the ESC 12. The processing chamber 12 provides a sealed space to form an atmosphere for a substrate or wafer 20 to be processed. Outside the processing chamber 10, a reaction gas source 22 is provided to supply the reaction gas. The reaction gas source 22 supplies the reaction gas for deposition, etching and/or ion implanting during semiconductor processing. Inside the processing chamber 10, the ESC 12 is supported by a mounting member 18. A media gas supplier 24 supplies a media gas to mediate heat transmission and cool the ESC 10.

In this example, the ESC 12 comprises a main body 26, a guide plate 28 to hold the wafer 20, and a bonding layer (not shown) to affix the guide plate 28 to the main body 26. During operation, the ESC 12 holds the wafer 20 by using the Coulomb force and the Johnsen-Rahbek effect generated when a voltage-applied dielectric material is charged, and its electrodes are polarized. The Johnsen-Rahbek effect is a force generated when a gap is formed by surface irregularities between the wafer 20 and a dielectric material. The gap is charged and polarized by current generated when voltage is applied thereto. The ESC 12 performs heat processing uniformly and minimizes generation of particles by attaching the wafer 20 to the main body 26. Over time, the ESC, and more particularly the upper surface of the guide plate 28, becomes worn with this harsh chemical and electrical environment within the processing chamber 10. And with the use of bonding methods to secure the guide plate 28 to the main body 26, it is difficult, time consuming and expensive to replace or refurbish an ESC.

The present disclosure addresses these challenges related to repairing or refurbishing an ESC in semiconductor processing applications, among other issues related to ESCs.

### SUMMARY

This section provides a general summary of the disclosure and is not a comprehensive disclosure of its full scope or all of its features.

In one form of the present disclosure, an electrostatic chuck (ESC) for use in semiconductor processing is provided that comprises a main body comprising an upper mounting surface, the upper mounting surface defining a surface profile. A guide plate is coupled to the upper mounting surface of the main body, and the guide plate comprises a lower mounting surface, the lower mounting surface defining a surface profile that follows the surface profile of the upper mounting surface of the main body. A heater is embedded within the main body, and a radio frequency (RF) electrode is embedded within the guide plate. The main body is coupled to the guide plate via a connection consisting of a mechanical interlock.

In variations of this ESC, which may be implemented individually or in any combination: the upper mounting surface of the main body comprises a recess having angled sidewalls, and the lower mounting surface of the guide plate comprises mating angled sidewalls to form the mechanical interlock; the upper mounting surface of the main body comprises a concave recess and the lower mounting surface of the guide plate comprises a mating convex projection to form the mechanical interlock; a first set of electrical terminations are in contact with the RF electrode and extend through the guide plate and through the main body; a second set of electrical terminations are in contact with the heater and extend through the main body; a thermal interface material is disposed between the upper mounting surface of the main body and the lower mounting surface of the guide plate; the guide plate comprises a first material and the main body comprises a second material different than the first material; a thermal conductivity of the first material is greater than a thermal resistivity of the second material; a thermal conductivity of the second material is greater than a thermal conductivity of the first material; a volume resistivity of the first material is greater than a volume resistivity of the second material; a volume resistivity of the second material is greater than a volume resistivity of the first material; the first material is selected from the group consisting of zirconium dioxide (ZrO₂), beryllium oxide (BeO), aluminum oxide (e.g., Al₂O₃), aluminum nitride (AlN), magnesium aluminate (Al₂MgO₄), calcium aluminate (Al₂CaO4), barium aluminate (BaO₆Al₂O₃), cordierite (Mg,Fe)₂Al₄Si₅O₁₈, silicon nitride (SiₓN_{y}), boron nitride (BNₓ) and silicon carbide (SiC); the second material is selected from the group consisting of aluminum nitride (AlN), silicon nitride (Si₃N₄), silicon carbide (SiC), boron nitride (BN), cordierite (Mg,Fe)₂Al₄Si₅O₁₈, silicon nitride, boron nitride, silicon (Si), stainless steel, aluminum, and superalloys (such as corrosion resistant nickel alloys sold under the trademarks HASTELLOY™ and INCONEL™); a material of the guide plate and a material of the main body are the same; a rotational locating feature is disposed between the main body and the guide plate; the rotational locating feature comprises a protrusion on one of the main body or the guide plate and a mating recess on one of the guide plate or the main body; a first set of electrical terminations are in contact with the RF electrode and extend through the guide plate and through the main body, wherein rotational locating feature comprises the first set of electrical terminations; a tuning heater is embedded within the guide plate, the tuning heater being disposed below the RF electrode; the connection between the main body and the guide plate does not include a bond layer; and the ESC further comprises a first set of electrical terminations in contact with the RF electrode and extending through the guide plate and through the main body; a second set of electrical terminations in contact with the heater and extending through the main body, and a shaft secured to a lower surface of the main body, the shaft comprising an inner space through which the first set of electrical terminations and the second set of electrical terminations extend.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a perspective view of an electrostatic chuck (ESC) in a processing chamber for use in semiconductor processing, according to the prior art;

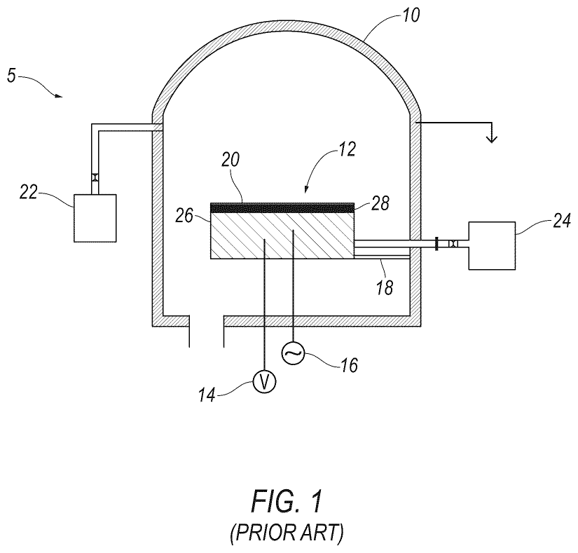

FIG. 2 is a perspective cross-sectional view of an ESC for use in semiconductor processing, according to the present disclosure;

FIG. 3 is a side view of the ESC of FIG. 2;

FIG. 4 is an exploded perspective cross-sectional view of the ESC of FIG. 2; and

FIG. 5 is an exploded side view of the ESC of FIG. 2.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

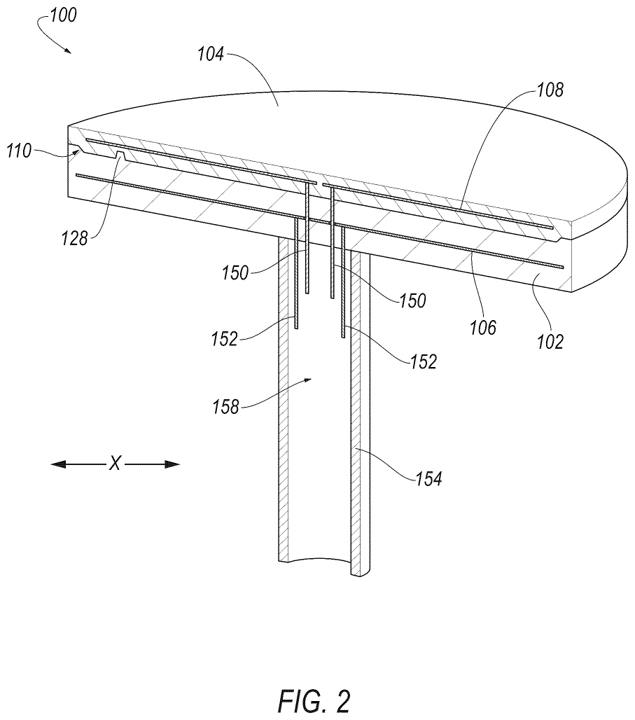

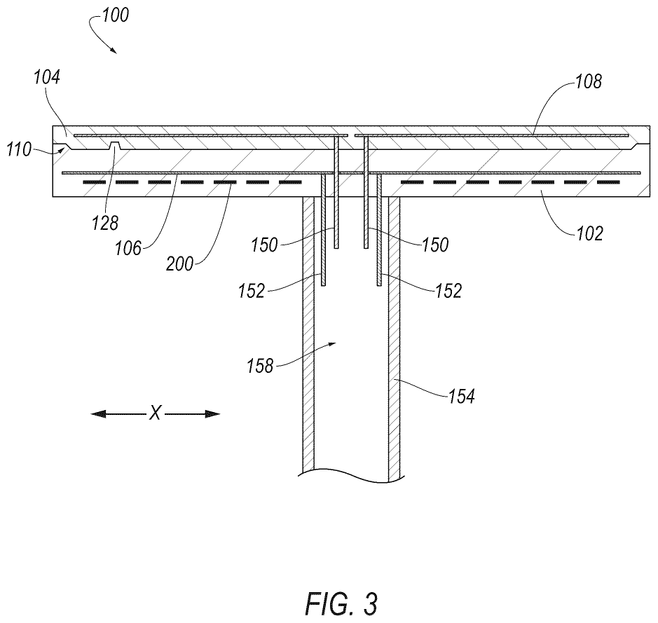

Referring to FIGS. 2-5, an electrostatic chuck (ESC) according to the present disclosure for use in semiconductor processing is illustrated and generally indicated by reference number 100. The ESC 100 generally includes a main body 102, a guide plate 104 coupled to the main body 102, a heater 106 embedded with the main body 102, and a radio frequency (RF) electrode 108 embedded within the guide plate 104. As set forth in greater detail below, the guide plate 104 is advantageously coupled to the main body 102 via a connection consisting of a mechanical interlock 110. In other words, the connection between the main body 102 and the guide plate 104 does not include a bond layer, thereby allowing for ease of replacement and repair of the upper portion of the ESC 100. In general, the mechanical interlock 110 is a mechanical connection between the guide plate 104 and the main body 102 that inhibits movement in a lateral direction (shown by arrow “X”) and/or rotational movement (shown in FIG. 3 by arrow “R”). Various forms of mechanical interlocks according to the teachings of the present disclosure are set forth in greater detail below.

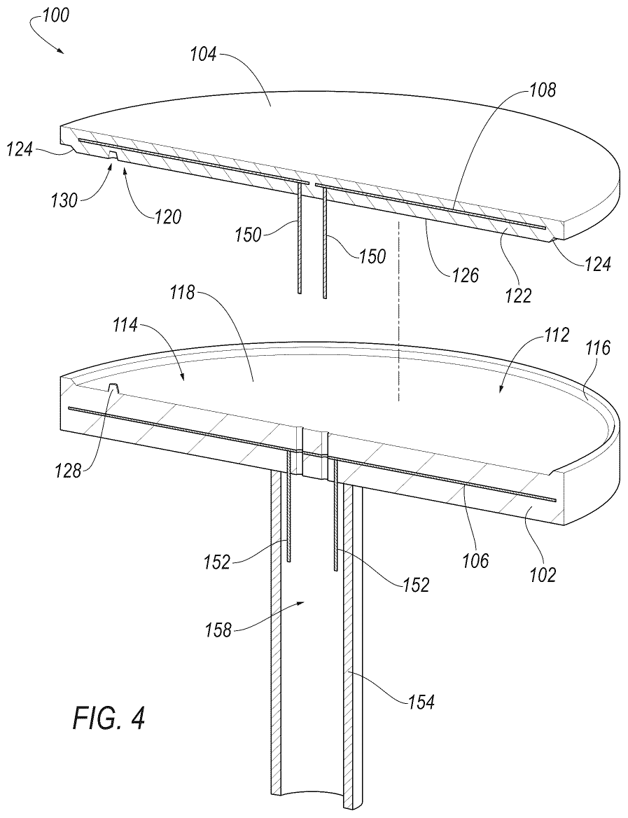

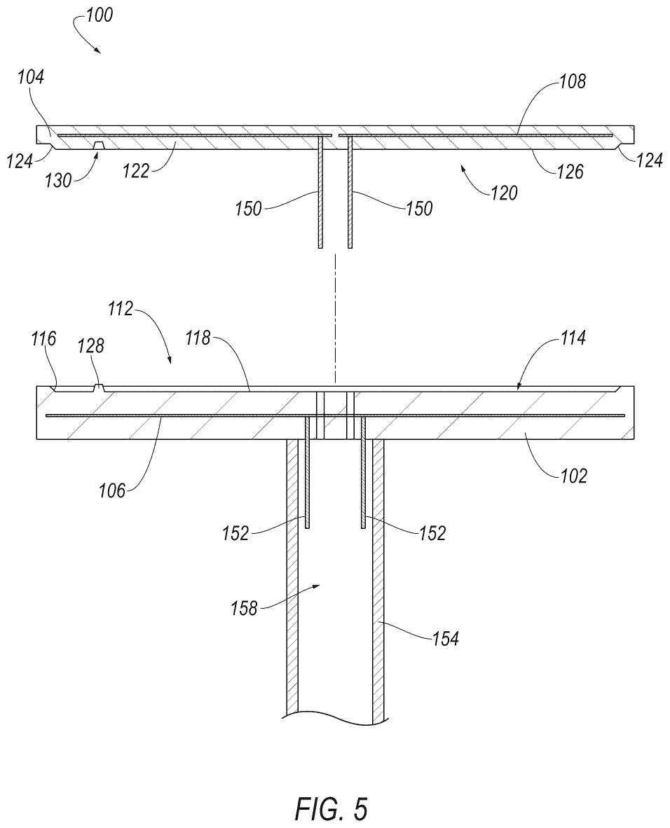

Referring specifically to FIGS. 4-5, the main body 102 is configured to support and cradle the guide plate 104. In one form, the main body 102 defines an upper mounting surface 112, and the upper mounting surface 112 defines a surface profile. In one variation of the present disclosure, the upper mounting surface 112 comprises a recess 114 having angled sidewalls 116 and a lower wall 118. The angled sidewalls 116 and the lower wall 118 together form the surface profile of the upper mounting surface 112 in this form of the present disclosure. In this variation, the upper mounting surface 112 is generally concave. In another form (not shown), the upper mounting surface 112 may be a convex shape (not shown). It should be understood that a variety of shapes and profiles for the upper mounting surface 112, including flat with the addition of an alignment feature as set forth in greater detail below, may be employed while remaining within the scope of the present disclosure.

The main body 102 comprises a material, such as by way of example, aluminum nitride (AlN), silicon nitride (e.g., Si₃N₄), beryllium oxide (BeO), silicon carbide (SiC), and boron nitride (BN), among others. It should be understood that a variety of materials suitable for use in an ESC for a semiconductor processing chamber may be employed while remaining within the scope of the present disclosure.

As shown in FIGS. 2-4, the guide plate 104 is coupled to the upper mounting surface 112 of the main body 102 via a mechanical interlock. In this form, the guide plate 104 includes a lower mounting surface 120 that forms a surface profile. The surface profile of the guide plate 104 follows the surface profile of the upper mounting surface 112 of the main body 102. In other words, the surface profile of the guide plate 104 compliments and mates with the surface profile of the upper mounting surface 112 of the main body 102. In this form, the lower mounting surface 120 comprises a convex projection 122 having a mating angled sidewall 124 and a mating lower surface 126. The convex projection 122 of the guide plate 104 aligns with and is configured to reside within the recess 114 of the main body 102. Accordingly, the convex projection 122 and the mating angled sidewall 124 are configured to compliment the recess 114 and the angled sidewalls 116 of the main body 102, thereby forming the mechanical interlock. This mechanical interlock inhibits a lateral and/or horizontal (along the direction of arrow “X”) movement of the guide plate 104 within the main body 102.

The guide plate 104 comprises a material, such as by way of example, zirconium dioxide (ZrO₂), beryllium oxide (BeO), aluminum oxide (Al₂O₃), aluminum nitride (AlN), and magnesium aluminate (Al₂MgO₄), boron nitride (BN), silicon nitride (Si₃N₄), boron carbide (B₄C), silicon carbide (SiC), cordierite ((Mg,Fe)₂Al₃(Si₅AlO₁₈) to (Fe,Mg)₂Al₃(Si₅AlO₁₈), mullite (3Al₂O₃2SiO₂), and quartz (SiO₂), among others. In one variation, the material of the guide plate 104 is different from the material of the main body 102. For example, the guide plate 104 is a BeO material, while the main body 102 is an AlN material. While the material of the guide plate 104 may be different from the material of the main body 102, it should be understood that the material of the guide plate 104 and the main body 102 may be the same type of material while remaining within the scope of the present disclosure. Additionally, a thermal resistivity of the material of the guide plate 104, in one form, is greater than a thermal resistivity of the material of the main body 102. However, in another form, a thermal conductivity of the main body 102 is greater than the thermal conductivity of the guide plate 104. Similarly, a volume resistivity (or electrical resistivity or specific electrical resistance) of the guide plate 104, in one form, is greater than a thermal resistivity of the material of the main body 102. However, in another form, a volume resistivity of the main body 102 is greater than the thermal conductivity of the guide plate 104. As used herein the term

The mechanical interlock 110 in another form also includes a rotational locating feature to inhibit rotational movement of the guide plate 104 within the main body 102. In this form, the rotational locating feature is disposed between the main body 102 and the guide plate 104 and comprises a protrusion 128 on one of the main body 102 or the guide plate 104 and a mating recess 130 on the other one of the guide plate 104 or the main body 102. In this form, protrusion 128 is on the main body 102 and extends from one of the angled sidewalls 116 as shown. A mating recess 130 is disposed within the guide plate 104, and more specifically within the mating angled sidewall 124 as shown. Accordingly, the connection between the main body 102 and the guide plate 104 does not include a bond layer with any of the variations illustrated and described herein. Therefore, the guide plate 104 may be easily removed for repair/refurbishment and a wider variety of materials may be employed for the overall ESC 100.

As further shown, the ESC 100 further comprises a first set of electrical terminations 150 in contact with the RF electrode 108 and extending through the guide plate 104 and through the main body 102. A second set of electrical terminations 152 are contact with the heater 106 and extend through the main body 102. A shaft 154 is secured to a lower surface 156 of the main body, and the shaft 154 comprises an inner space 158 through which the first set of electrical terminations 150 and the second set of electrical terminations 152 extend and are connected to a power supply and controller (not shown). In one form, the first set of electrical terminations 150 and the second set of electrical terminations 152 function as the rotational locating feature as set forth above. In other words, the fixed position of the first set of electrical terminations 150 and the second set of electrical terminations 152 inhibit the guide plate 104 and the main body 102 from moving relative to each other.

The ESC 100 in another form further comprises a thermal interface material (not shown) disposed between the upper mounting surface 112 of the main body 102 and the lower mounting surface 120 of the guide plate 104. The thermal interface material (commonly referred to as a “paste” or “grease” in the art) may be disposed on the main body 102, however, the thermal interface material 160 may be disposed on one or both of the main body 102 and the guide plate 104 while remaining within the scope of the present disclosure. The thermal interface material is generally a material that is configured to fill any gaps or voids between the main body 102 and the guide plate 104 after assembly, which may be due to manufacturing variations or erosion over time during use. The thermal interface material also functions as a heater or thermal spreader for more uniform temperature distribution from the heater 106. The thermal interface material may include, byway of example, ceramic-based silicone compound, among others, which is a function of the material of the main body 102, the guide plate 104, and the operating temperature of the ESC 100.

Referring back to FIG. 3, the ESC 100 is another form includes a tuning heater 200 embedded within the guide plate 104. The tuning heater 200 is disposed below the RF electrode 108 as shown and is configured to provide supplemental and tailored heat to the upper surface of the ESC 100, in addition to heat being provided by the heater 106. Examples of tuning heaters 200 are illustrated and described in U.S. Pat. Nos. 9,263,305 and 9,123,755, which are commonly owned with the present application and the contents of which are incorporated herein by reference in their entirety.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. An electrostatic chuck (ESC) for use in semiconductor processing, the ESC comprising:
a main body comprising an upper mounting surface, the upper mounting surface defining a surface profile;
a guide plate coupled to the upper mounting surface of the main body, the guide plate comprising a lower mounting surface, the lower mounting surface defining a surface profile that follows the surface profile of the upper mounting surface of the main body;
a heater embedded within the main body; and
a radio frequency (RF) electrode embedded within the guide plate,
wherein the main body is coupled to the guide plate via a connection consisting of a mechanical interlock.

2. The ESC according to claim 1, wherein the upper mounting surface of the main body comprises a recess having angled sidewalls, and the lower mounting surface of the guide plate comprises mating angled sidewalls to form the mechanical interlock.

3. The ESC according to claim 1, wherein the upper mounting surface of the main body comprises a concave recess and the lower mounting surface of the guide plate comprises a mating convex projection to form the mechanical interlock.

4. The ESC according to claim 1, further comprising a first set of electrical terminations in contact with the RF electrode and extending through the guide plate and through the main body.

5. The ESC according to claim 1, further comprising a second set of electrical terminations in contact with the heater and extending through the main body.

6. The ESC according to claim 1, further comprising a thermal interface material disposed between the upper mounting surface of the main body and the lower mounting surface of the guide plate.

7. The ESC according to claim 1, wherein the guide plate comprises a first material and the main body comprises a second material different than the first material.

8. The ESC according to claim 7, wherein a thermal conductivity of the first material is greater than a thermal resistivity of the second material.

9. The ESC according to claim 7, wherein a thermal conductivity of the second material is greater than a thermal conductivity of the first material.

10. The ESC according to claim 7, wherein a volume resistivity of the first material is greater than a volume resistivity of the second material.

11. The ESC according to claim 7, wherein a volume resistivity of the second material is greater than a volume resistivity of the first material.

12. The ESC according to claim 7, wherein the first material is selected from the group consisting of zirconium dioxide, beryllium oxide, aluminum oxide, aluminum nitride, magnesium aluminate, calcium aluminate, barium aluminate, cordierite, silicon nitride, boron nitride and silicon carbide.

13. The ESC according to claim 7, wherein the second material is selected from the group consisting of aluminum nitride, silicon nitride, silicon carbide, boron nitride, cordierite, silicon nitride, boron nitride, silicon, stainless steel, aluminum, and superalloy.

14. The ESC according to claim 1, wherein a material of the guide plate and a material of the main body are the same.

15. The ESC according to claim 1, further comprising a rotational locating feature disposed between the main body and the guide plate.

16. The ESC according to claim 15, wherein the rotational locating feature comprises a protrusion on one of the main body or the guide plate and a mating recess on one of the guide plate or the main body.

17. The ESC according to claim 15, further comprising a first set of electrical terminations in contact with the RF electrode and extending through the guide plate and through the main body, wherein rotational locating feature comprises the first set of electrical terminations.

18. The ESC according to claim 1, further comprising a tuning heater embedded within the guide plate, the tuning heater being disposed below the RF electrode.

19. The ESC according to claim 1, wherein the connection between the main body and the guide plate does not include a bond layer.

20. The ESC according to claim 1, further comprising:
a first set of electrical terminations in contact with the RF electrode and extending through the guide plate and through the main body;
a second set of electrical terminations in contact with the heater and extending through the main body; and
a shaft secured to a lower surface of the main body, the shaft comprising an inner space through which the first set of electrical terminations and the second set of electrical terminations extend.
